(19) United States
(12) Patent Application Publication
(10) Pub. No.: US 2006/0160326 A1
(43) Pub. Date: Jul. 20, 2006

(54) Method for rounding top corners of isolation trench in semiconductor device

(76) Inventor: Yong Jun Lee, Bucheon-si (KR)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/318,587

(22) Filed: Dec. 28, 2005

(30) Foreign Application Priority Data
Dec. 29, 2004 (KR) 10-2004-0115795

(51) Int. Cl. H01L 21/76

(52) U.S. Cl. 438/424

(57) ABSTRACT

A method for forming an isolation trench in a semiconductor device includes the steps of: forming a pad oxide layer over a semiconductor substrate; forming a pad nitride layer over the pad oxide layer; forming a photoresist pattern defining an isolation area on the pad nitride layer; forming a trench in the substrate by etching the pad nitride layer, the pad oxide layer, and the substrate, using the photoresist pattern as a mask; filling the trench with a dielectric material; and oxidizing a portion of the substrate in the vicinity of top corners of the trench.

This application claims the benefit of priority of Korean Application No. 10-2004-0115795, filed on Dec. 29, 2004, which is incorporated by reference herein in its entirety.

### BACKGROUND OF THE INVENTION

1. Technical Field

The present invention relates generally to a semiconductor device manufacturing technology, and particularly to a method for rounding top corners of isolation trench in a semiconductor device.

2. Description of the Related Art

A manufacturing process of a highly integrated semiconductor circuit involves forming a variety of components, such as a transistor, capacitor, metal wiring, etc., in very restricted regions, and forming highly insulated regions to prevent parasitic current leakage between the components.

Conventionally, a local oxidation of silicon (LOCOS) field oxide, formed by oxidizing a silicon substrate, has been widely used for isolating the components of a semiconductor circuit. However, as the integration density increases, a LOCOS field oxide has become disadvantageous to the formation of integrated circuits, because a LOCOS field oxide generally includes a bird's beak that may invade an active device region. Accordingly, a lot of alternative isolation technologies have been proposed. A typical example of such alternative isolation technologies is shallow trench isolation (STI), which has a superior insulating performance and a relatively small formation area, and has been widely used for isolating transistors in higher integrated MOSFET (Metal Oxide Semiconductor Field Effect Transistor) and BJT (Bipolar Junction Transistor) circuits.

In a typical STI process, a pad dielectric layer, such as silicon dioxide, silicon nitride, etc., is formed on the entire surface of a silicon substrate to protect active device regions. A photoresist layer is formed and patterned on the pad nitride by a photolithography process. The photoresist pattern defines openings over isolation areas of the substrate.

After the definition of the isolation areas, the exposed portions of the pad dielectric layer are removed by an anisotropic etching process using the photoresist pattern as an etching mask. This etching process is performed to expose the isolation areas in which a trench will be formed. Next, the photoresist pattern is removed, and the exposed isolation areas of the substrate are then etched to a predetermined depth by an anisotropic etching process using the pad dielectric layer as an etching mask.

After the trench etch, a trench oxide, e.g., a chemical vapor deposited (CVD) silicon dioxide, is formed over the entire substrate and in the trench. The trench oxide over the active device regions is removed by planarization of the substrate by chemical-mechanical polishing (CMP) using the pad dielectric layer over the active device regions as a stop layer.

FIG. 1 shows an SEM micrograph of two adjacent isolation trenches filled with the trench oxide in a semiconductor device. Reference numerals 10, 20, and 30 respectively represent the silicon substrate, the trench oxide, and a gate oxide formed in subsequent process.

As FIG. 1 shows, silicon substrate 10 has sharp protrusions at upper corners (A) of the isolation trenches, because the trenches are formed by anisotropic etching process. When gate oxide 30 is formed on the active device area and partly on the trench oxide, gate oxide 30 may have cracks over upper corners (A), due to the sharp profile of silicon substrate 10.

The cracks of gate oxide 30 or sharp profile of substrate 10 in the vicinity of top corners A of the trenches may deteriorate the performance of the semiconductor device, particularly when the semiconductor device is a flash memory device to be programmed or erased by electrons tunneling through the gate oxide. Repeated programming and erasing may generate a strong electric field in the sharp corners of the trenches, which may damage the semiconductor device.

### SUMMARY

The present invention provides a method for improving the profile of a semiconductor substrate in the vicinity of top corners of isolation trenches in a semiconductor device. The electric field concentration and silicon lattice damages in the vicinity of top corners of the isolation trenches can be effectively alleviated.

A method for forming an isolation trench in a semiconductor device, consistent with embodiments of the present invention, includes the steps of: forming a pad oxide layer over a semiconductor substrate; forming a pad nitride over the pad oxide layer; forming a photoresist pattern defining an isolation area on the pad nitride layer; forming a trench in the substrate by etching the pad nitride layer, the pad oxide layer, and the substrate, using the photoresist pattern as a mask; filling the trench with a dielectric material; and oxidizing a portion of the substrate in the vicinity of top corners of the trench.

Before filling the trench, a liner oxide may be formed on a sidewall of the trench to protect the surface of the substrate. In addition, the liner oxide may be formed by a dry or wet oxidation process.

These and other aspects of the present invention will become evident by reference to the following description of the invention, often referring to the accompanying drawings.

### BRIEF DESCRIPTION OF DRAWINGS

The accompanying drawings, which are incorporated in and constitute a part of this specification, illustrate embodiments of the invention and, together with the description, serve to explain the features, advantages, and principles of the invention.

In the drawings,

FIG. 1 is a scanning electron microscopy (SEM), in cross-sectional view, of an isolation trench structure formed by conventional method for forming shallow trench isolation in a semiconductor device;

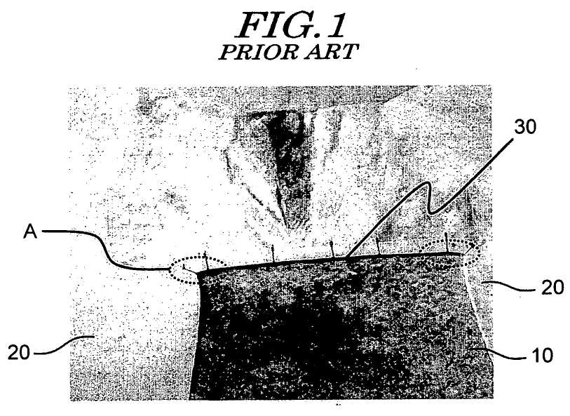

FIG. 2 is a cross-sectional view of shallow isolation trench, illustrating the high temperature re-oxidation process consistent with the present invention; and

FIG. 3 is a SEM image of a semiconductor substrate, illustrating a cross-section of adjacent isolation trenches formed by a method for rounding top corners of the isolation trench, consistent with the present invention.

### DETAILED DESCRIPTION OF THE INVENTION

Reference will now be made in detail to the present embodiments of the invention, examples of which are illustrated in the accompanying drawings. Wherever possible, the same reference numbers will be used throughout the drawings to refer to the same or like parts.

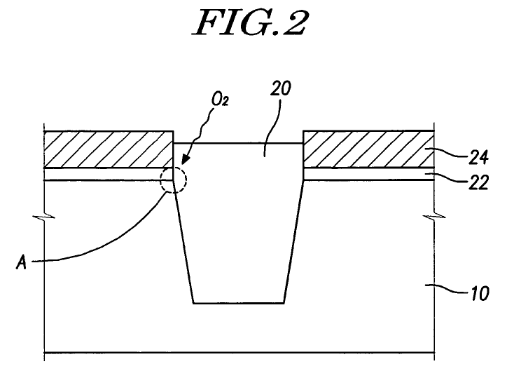

FIG. 2 is a cross-section view showing an isolation trench filled with a dielectric material. A method for forming the structure in FIG. 2 is described below.

First, a layer of pad silicon dioxide 22 and a layer of pad silicon nitride 24 are sequentially deposited in thicknesses of about 150 Å and about 2000 Å, respectively, over an entire surface of a silicon substrate 10. Next, a photoresist pattern (not shown) exposing a portion of the pad nitride layer over isolation areas of substrate 10 is formed on pad nitride layer 24 by a photolithography process. The photoresist pattern defines openings over isolation regions in which trenches will be formed.

After the definition of photoresist pattern, the exposed portion of pad nitride layer 24 is removed, exposing a portion of pad oxide layer 22. The exposed portion of pad oxide layer 22 is then removed, exposing the isolation areas of substrate 10. Then, the exposed isolation areas of substrate 10 are etched to a predetermined depth to form the trenches (not numbered). The trench etch is performed by a suitable etching process. For example, an anisotropic etching process such as a reactive ion etch (RIE) may be performed to form the trenches. After the trench etch, the photoresist pattern on pad nitride layer 24 is removed, and substrate 10 is cleaned.

Next, a liner oxide (not shown) is formed in the trenches. The liner oxide is formed to a thickness of about 270 Å by oxidizing the trench sidewalls. This liner oxidation step eliminates etch damages to the trench sidewalls. Also, silicon lattice stress at the interface between the trench sidewalls and a trench oxide to be deposited to fill the trench may induce interface traps, i.e., electrically active defects present at the oxide/semiconductor interface. The liner oxidation buffers the silicon lattice stress and thereby helps reduce interface traps.

After the liner oxidation, a dielectric layer, such as silicon dioxide, is deposited by chemical vapor deposited (CVD) over the entire surface of substrate 10 and in the trenches. The dielectric layer deposited outside the trenches is removed during a planarization process such as chemical-mechanical polishing (CMP) to form trench oxide 20 in the trenches.

The trenches have a sharp profile at the top corners thereof, which can be rounded or smoothed by a re-oxidation process. Specifically, during the re-oxidation process, oxygen permeates into the trench oxide, especially top portions of the trench oxide, at a high temperature, e.g., >1000° C., and in an oxygen, e.g., dry or wet ambient. FIG. 2 schematically illustrates the process of oxygen's permeation into the top corners, indicated as A, of the trenches.

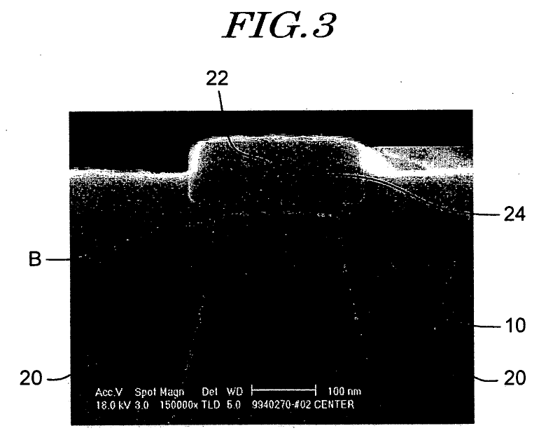

The oxygen permeating into the trenches may practically concentrate on the region A, and then react with silicon to form silicon dioxide. This local re-oxidation rounds the top corner of the trenches by consuming a small amount of silicon in silicon substrate 10. FIG 3 shows an SEM micrograph of two isolation trenches having a round or smooth edge profile in the region indicated as B.

After the re-oxidation process, pad nitride layer 24 and pad oxide layer 24 are removed, resulting in a highly planar substrate with isolated device regions.

While the invention has been shown and described with reference to certain embodiments thereof, it will be understood by those skilled in the art that various changes in form and details may be made therein without departing from the spirit and scope of the invention as defined by the appended claims.

What is claimed is:

1. A method for forming an isolation trench in a semiconductor device, comprising the steps of:
forming a pad oxide layer over a semiconductor substrate;
forming a pad nitride layer over the pad oxide layer;
forming a photoresist pattern defining an isolation area on the pad nitride layer;
forming a trench in the substrate by etching the pad nitride layer, the pad oxide layer, and the substrate, using the photoresist pattern as a mask;
filling the trench with a dielectric material; and
oxidizing a portion of the substrate in the vicinity of top corners of the trench.

2. The method of claim 1, further comprising the step of forming a liner oxide on a sidewall of the trench before filling the trench.

3. The method of claim 1, wherein the oxidizing comprises a dry or wet oxidation process.

4. A semiconductor device with shallow trench isolation, wherein the shallow trench isolation is formed by a method of claim 1.

5. A semiconductor device with shallow trench isolation, wherein the shallow trench isolation is formed by a method of claim 2.

6. A semiconductor device with shallow trench isolation, wherein the shallow trench isolation is formed by a method of claim 3.
